(19) United States
(12) Patent Application Publication
(10) Pub. No.: US 2026/0254443 A1
(43) Pub. Date: Aug. 27, 2026

(54) DYNAMIC ZONE-BASED NON-LINEARITY MITIGATION OF PHASE INTERPOLATOR

(71) Applicant: Marvell Asia Pte Ltd, Singapore (SG)

(72) Inventors: Amit Kumar Singh, Bangalore (IN); Manisha Gambhir, Cupertino, CA (US); Ahmed Mostafa, San Jose, CA (US); Umesh Kumar Shukla, Bangalore (IN); Purushotham Brahmavar Ramakrishna, Bangalore (IN)

(73) Assignee: Marvell Asia Pte Ltd, Singapore (SG)

(21) Appl. No.: 19/548,463

(22) Filed: Feb. 24, 2026

Related U.S. Application Data
(60) Provisional application No. 63/763,463, filed on Feb. 26, 2025.

(51) Int. Cl. H03K 5/13

(52) U.S. Cl. CPC H03K 5/13

(57) ABSTRACT

A phase interpolator (PI) for clock and data recovery (CDR) in a high-speed receiver implements nonlinearity mitigation. The PI interpolates between adjacent phase-shifted clock signals based on digital PI-codes to generate a sampling clock. To reduce phase nonlinearity at high frequencies, the PI applies zone-based dynamic biasing to phase interpolation elements. A bias generator selects and applies one or more bias values to PI unit cells based on a phase zone corresponding to the PI-code. The applied bias adjusts operating characteristics of the interpolation elements, such as bias current or transconductance, to reduce differential nonlinearity and integrated nonlinearity across the PI phase range. In some embodiments, PI unit cells are arranged in groups that receive independently selectable dynamic or fixed biases. The architecture improves phase linearity and timing alignment with low area and power overhead.

### PRIORITY APPLICATION

This patent application claims priority to and/or receives benefit from U.S. Provisional Application No. 63/763,463, titled, “Zone base Piece-wise Static Non-linearity Correction for CML Phase Interpolators”, filed on Feb. 26, 2025. The U.S. Provisional Application is hereby incorporated by reference in its entirety.

### BACKGROUND

High-speed, high-bandwidth communication systems are integral to modern computing and networking applications. These systems are designed to facilitate efficient and reliable data transmission over various media, including optical fibers, copper cables, and wireless channels. Advances in communication technologies, such as signal modulation, error correction, and clock recovery, can ensure data integrity, reduce latency, and maintain synchronization across devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an exemplary electronics system, according to some embodiments of the disclosure.

FIG. 2 illustrates an implementation of a clock and data recovery (CDR) loop, according to some embodiments of the disclosure.

FIG. 3 provides a visual representation of phase sectors and phase zones, according to some embodiments of the disclosure.

FIG. 4 is a block diagram of an example phase interpolator (PI) with a bias generator, according to some embodiments of the disclosure.

FIG. 5 is a block diagram of a second example PI with a bias generator configured to receive a correction code, according to some embodiments of the disclosure.

FIG. 6 is a block diagram of the bias generator, according to some embodiments of the disclosure.

FIG. 7 illustrates an example implementation of the voltage bias bank, according to some embodiments of the disclosure.

FIG. 8 illustrates an example grouping of PI unit cells receiving different bias values, according to some embodiments of the disclosure.

FIG. 9 is a flow chart illustrating a method for nonlinearity correction for a PI, according to some embodiments of the present disclosure.

### DETAILED DESCRIPTION

### Overview

Digital signal processors (DSPs), such as optical DSPs and coherent DSPs, can enable high-bandwidth optical interconnects that deliver ultra-high throughput while optimizing for low-latency and energy-efficient data transfer. Such DSPs can offer seamless connectivity across a variety of computing environments, including AI, cloud computing, and enterprise systems, and 5G infrastructure.

In many designs, minimizing chip area is critical for devices that incorporate a DSP. Phase-locked loops (PLLs) occupy significant silicon area, so sharing a single PLL across multiple lanes is an effective strategy for optimizing area utilization. Additionally, placing multiple PLLs in close proximity can introduce noise and crosstalk; using one shared PLL for several lanes not only conserves area but also mitigates these interference issues.

A shared PLL generates a high-frequency reference clock that can be distributed to multiple lanes, e.g., to all lanes on the device. In high-speed serial links, each lane may experience unique skew and jitter, and each lane may have unique data alignment requirements. So, to tune the clock phase for each lane, the shared PLL may be coupled to a per-lane delay-locked loop (DLL) and per-lane phase interpolator (PI). The DLL receives the reference clock from the PLL and produces multiple phase-shifted versions. The PI takes these DLL-generated phases and, using a digital PI-code, interpolates between them to create a finely tuned output phase. This process enables each lane to generate a clock signal precisely aligned with its incoming data.

Phase interpolation can be challenging in high frequency implementations, e.g., above 28 gigahertz (GHz). For example, it can be difficult for existing PIs to meet bit error rate (BER) and linearity expectations. The non-linearity of a PI is often measured in terms of differential non-linearity (DNL) and integrated non-linearity (INL), where INL is an accumulation of DNL error, such that DNL errors over time lead to high INL errors. High INL errors limit the ability of the CDR to track the incoming data phase, limiting the receiver's performance.

Accordingly, phase interpolation solutions that improve or correct INL and reduce PI error, particularly for high-frequency applications, are described herein. It is desirable for a solution for INL improvement to have minimal area and power overhead. In addition, it is desirable to provide INL improvements even at high data rates, e.g., at over 200 Gbps; this can be achieved using dynamic or programmable PI correction.

A PI architecture disclosed herein mitigates nonlinearity across the PI's phase range through the application of dynamic, zone-dependent biasing. The PI includes unit cells and a bias generator coupled to the unit cells. The bias generator supplies a dynamic bias that varies based on a phase zone, where the phase zone corresponds to a portion of the PI's phase range. For example, the PI may have eight phase sectors and two zones within each sector. The PI receives a PI-code identifying a particular interpolated phase within one of the phase zones for the PI to generate. By identifying the zone associated with the current PI-code, the bias generator can apply a bias specific to the current zone to at least some of the unit cells, where the bias tunes the delay of the unit cells. Zone-based biasing selects a bias based on the portion of the phase curve where a particular non-linearity is known to occur. In some embodiments, unit cells are grouped, and different biases may be applied to different groups of unit cells. Applying different biases can address structural imbalance among the unit cell groups. Overall, this biasing scheme can correct or reduce DNL before it accumulates into high INL. This improves the accuracy and linearity of the generated clock phase, particularly in high-frequency environments where conventional interpolators exhibit large deviations from ideal behavior.

In some embodiments, the bias generator includes a voltage bias bank coupled to selection circuitry for selecting a voltage to apply to a unit cell or group of unit cells. The voltage bias bank may be implemented as a resistive network having multiple tap points, each of which provides a corresponding bias voltage. The selection circuitry couples one of these bias voltages to the PI unit cell based on the current phase zone. This structure enables fine-grained phase correction without the area or power overhead of complex interpolation algorithms or non-linear digital-to-analog (DAC) structures. In some implementations, the bias generator also includes mapping circuitry that associates each phase zone with a respective bias value or correction setting, allowing the PI to implement unique bias corrections across the entire phase range.

As noted above, in some configurations, the PI includes multiple PI unit cells arranged in groups, with at least two of the groups receiving different bias levels. A first subset of unit cells may receive a first dynamic bias, while a second subset of unit cells receives a second dynamic bias that is controlled independently from the first dynamic bias. In some implementations, one or more groups of unit cells receive a fixed bias that does not change based on the phase zone. For example, a PI may include two groups of PI unit cells with programmable bias, where each group is biased independently, and two groups of PI unit cells with fixed bias. Group-wise biasing allows the architecture to target unit-cell regions that disproportionately contribute to nonlinearity, improving phase uniformity. Grouping unit cells together (e.g., rather than biasing each unit cell independently), and using zone-based biasing (e.g., rather than biasing each PI-code independently), improves non-linearity while keeping the bias circuitry compact and efficient.

### Exemplary Computing System

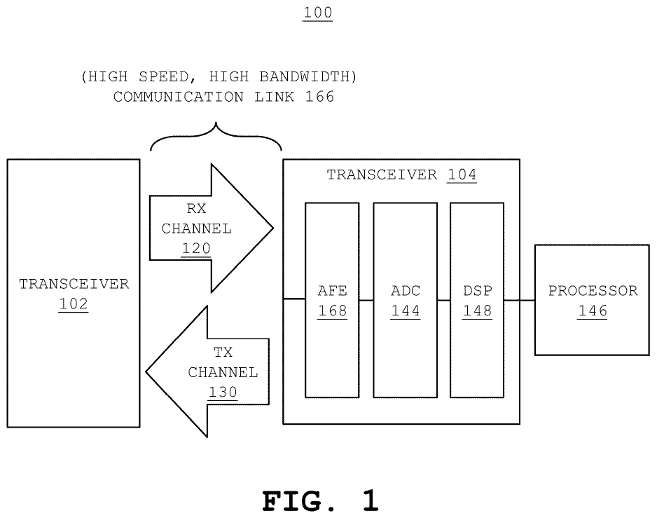

FIG. 1 illustrates an exemplary electronics system 100, according to some embodiments of the disclosure. Electronics system 100 can be used in high-speed, high-bandwidth communication applications. Electronics system 100 can include one or more components to carry out functionalities, including, among other things, effective signal transmission, reception, diagnostics, and clock recovery functionality. Electronics system 100 includes transceiver 102 and transceiver 104. Transceiver 104 can carry out communication functionalities for processor 146. For simplicity, the processor for which transceiver 102 is carrying out communication functionalities is omitted in the figure.

Processor 146 may perform data processing tasks. Processor 146 can include one or more suitable types of processors, and one or more suitable number of processors. Processor 146 may be a single-core processor, or a multi-core (e.g., ARM or x86 processor cores). Examples of processor 146 may include a central processing unit (CPU), a graphics processing unit (GPU), a field-programmable gate array (FPGA), a tensor processing unit (TPU), a data processing unit (DPU), a DSP, an application specific integrated circuit (ASIC), etc. Processor 146 can execute instructions or commands of an operating system. Processor 146 can perform operations and/or computations for an application of electronics system 100.

Transceiver 104 can enable transmission and reception of signals over (high-speed, high-bandwidth) communication link 166. In this example, communication link 166 can include one or more of: receive (RX) channel 120, and transmit (TX) channel 130. RX channel 120 can have one or more RX data lanes received at transceiver 104. TX channel 130 can have one or more TX data lanes transmitted from transceiver 104.

Transceiver 102 can transmit data over RX channel 120 to transceiver 104 and can include circuitry to support transmission of data. Incoming data signals transmitted over RX channel 120 can be received by transceiver 104. Transceiver 104 has circuitry that processes the received data signals. Transceiver 104 can include an analog front-end (AFE) 168, which may include one or more amplifiers or other analog circuits to process the received data signals before the data signals are provided to one or more analog-to-digital converters (ADC) 144. For example, AFE 168 may include phase interpolator 220 and delay-locked loop 230 described below.

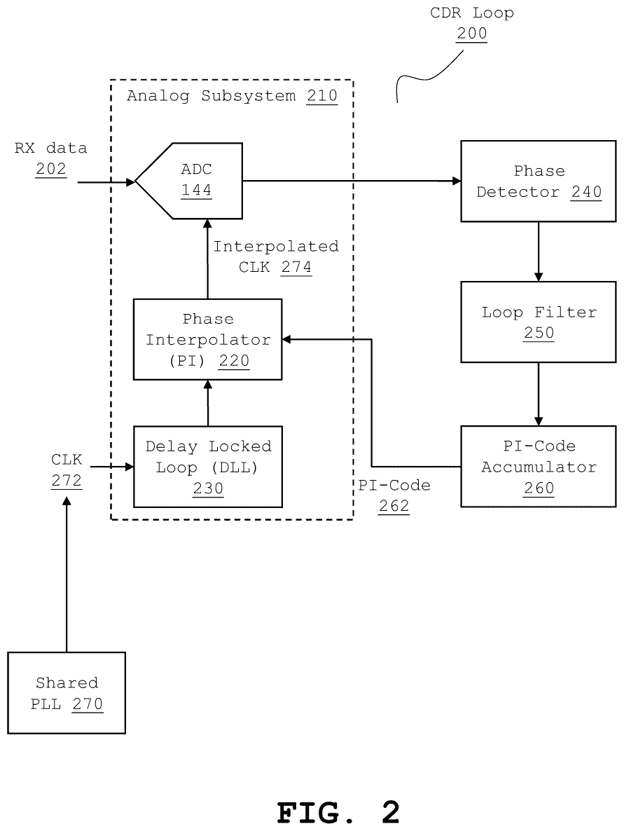

ADC 144 can digitize the analog signals and output digital outputs or digital samples for further processing by DSP 148. For high-speed, high-bandwidth data interfaces, transceiver 104 may include multiple time-interleaved ADCs used to sample an analog signal received on RX channel 120 to achieve the baud rate of the communication channel. Time-interleaved ADCs 144 can take turns, one after another, or in a randomized fashion, to sample the received analog signal at different sampling points to produce the digitized samples of the received analog signal. ADC(s) 144 and AFE 168 may be part of an analog subsystem, e.g., analog subsystem 210 described with respect to FIG. 2.

Transceiver 104 can transmit signals to transceiver 102 via TX channel 130, and transceiver 104 can include additional circuitry to prepare data signals to be transmitted over TX channel 130. Transceiver 104 can include TX circuitry to ensure faithful signal transmission over communication link 166.

DSP 148 can manage data processing tasks within transceiver 104. DSP 148 can include circuitry to perform one or more operations or computations. DSP 148 can include circuitry that can execute instructions and carry out one or more operations or computations. Examples of operations or computations can include, but are not limited to, diagnostics, control algorithms, signal processing, filtering, decision making or slicing, and equalization. Example components of DSP 148 are shown in FIG. 2 and FIGS. 4-8, described below.

While the description is focused on transceiver 104, it is envisioned that various embodiments described herein are applicable to transceiver 102. It is also envisioned that various embodiments described herein are applicable to receivers, and not necessarily transceivers.

### Example CDR Loop

FIG. 2 illustrates an implementation of a CDR loop 200, according to some embodiments of the disclosure. CDR loop 200 includes an analog subsystem 210, which includes ADC 144, e.g., the ADC 144 of FIG. 1. In some embodiments, CDR loop 200 corresponds to a single lane of a multi-lane receiver, where each lane has an associated ADC 144 and its own CDR loop 200. Analog subsystem 210 further includes phase interpolator (PI) 220 and delay-locked loop (DLL) 230.

ADC 144 receives RX data 202, which it samples and digitizes based on an interpolated clock 274 signal (which may also be referred to as a sampling clock or recovered clock) from PI 220. ADC 144 outputs the digitized data into the digital portion of CDR loop 200, which includes phase detector 240, loop filter 250, and PI-code accumulator 260. Phase detector 240, loop filter 250, and PI-code accumulator 260, along with shared phase-locked loop (PLL) 270, may be implemented by DSP 148.

Phase detector 240 outputs a phase error signal to loop filter 250. Loop filter 250 processes the phase error signal to filter out noise and generate a control signal that stabilizes the loop response.

PI-code accumulator 260 receives the control signal from loop filter 250 and may integrate or accumulate the filtered control signal to generate an updated PI-code 262. PI-codes 262 are digital values that represent the desired phase adjustment for PI 220; PI-codes 262 are used to adjust PI 220 for precise clock alignment to an optimal sampling point of RX data 202. PI-code accumulator 260 may generate PI-codes 262 by incrementally adjusting its accumulator's value in response to the filtered phase error from loop filter 250. An updated PI-code 262 is sent to PI 220, which uses PI-code 262 to interpolate between multiple clock phases and produce the interpolated clock 274 that is precisely aligned with the incoming data. By continuously updating PI-codes 262, PI-code accumulator 260 enables CDR loop 200 to track and correct timing variations, ensuring robust data recovery even in the presence of jitter or drift.

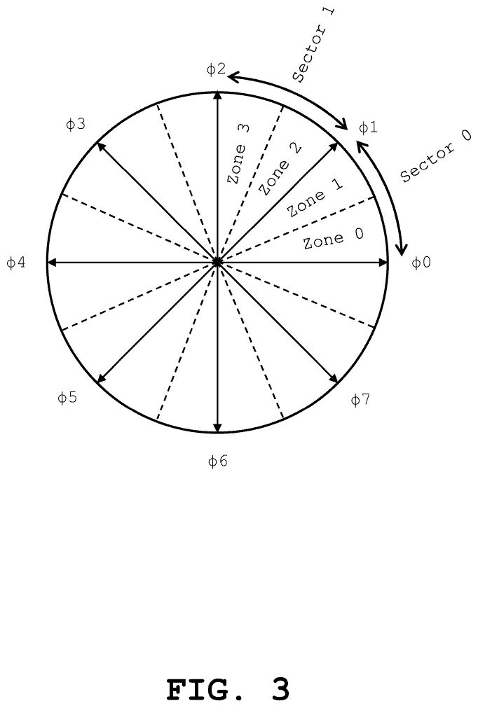

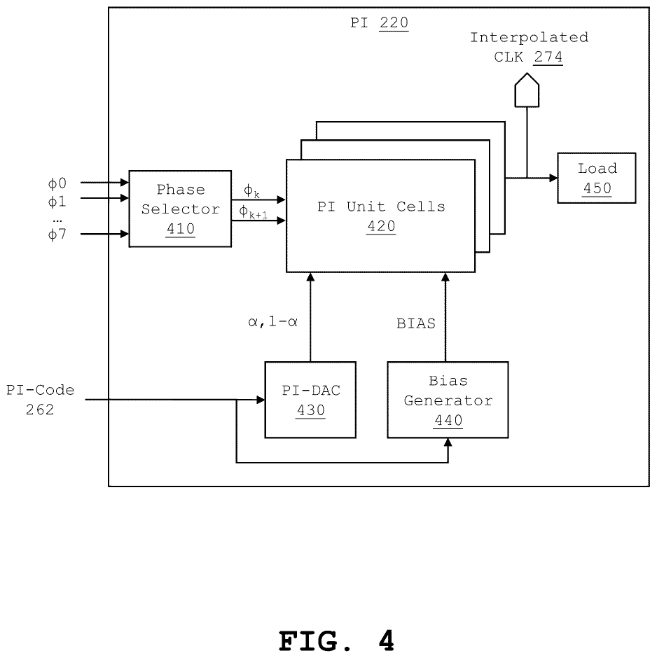

Shared PLL 270 generates a high-frequency reference clock signal, denoted as CLK 272, which is distributed to multiple lanes within transceiver 104. Within each lane, DLL 230, or another implementation of a multiphase generator, receives the reference clock signal CLK 272 from shared PLL 270 and produces multiple phase-shifted versions of this clock. These phase-shifted outputs from DLL 230 are input to PI 220. An example phase diagram is shown in FIG. 3, described below. PI 220 utilizes the phase-shifted clocks, along with PI-codes 262, to interpolate and generate a finely tuned sampling clock (i.e., the interpolated clock 274) that is precisely aligned with the incoming RX data 202. PI-code 262, which is continuously updated by the PI-code accumulator 260, determines the specific phase adjustment applied by PI 220, enabling accurate timing alignment and robust data recovery in the presence of channel variations and jitter. PI 220 provides the interpolated clock 274 to ADC 144, which uses the interpolated clock 274 to determine sampling instants for RX data 202. FIGS. 4-8, described below, illustrate example implementations of PI 220 that include zone-based biasing to mitigate non-linearity of PI 220.

### Example Phase Diagram for PI

FIG. 3 provides a visual representation of phase sectors and phase zones, according to some embodiments of the disclosure. As noted above, PI 220 receives phase-shifted clocks from DLL 230. In the example of FIG. 3, DLL 230 outputs eight equally-spaced phases, and each of φ0, φ1, . . . , φ7 corresponds to a different phase from DLL 230. The region between two consecutive phases is referred to as a sector. For example, Sector 0 is between φ0 and φ1, and Sector 1 is between φ1 and φ2. PI 220 interpolates between an adjacent pair of phases from DLL 230. That is, PI 220 uses PI-code 262 to determine both the selected adjacent phase pair (corresponding to a sector) and a position within that sector. The region spanned by the sectors represents the phase range of the PI 220.

In some embodiments, each sector is further divided into zones. For example, as described further below, elements for phase interpolation, referred to herein as PI unit cells or unit cells, may be biased based on the zone corresponding to the PI-code 262. In this example, each sector is divided into two zones, e.g., Sector 0 includes two zones (labelled here as Zone 0 and Zone 1), and Sector 1 includes two zones (here, Zone 2 and Zone 3). In total, the phase diagram includes 8 sectors (which may be referred to as Sector 0 through Sector 7) and 16 zones (which may be referred to as Zone 0 through Zone 15). Different PI-codes 262 are associated with different sectors and zones. For example, the CDR loop 200 may have 256 PI-codes, where PI-codes 0 through 15 are evenly distributed across Zone 0 of Sector 0, PI-codes 16-31 are evenly distributed across Zone 1 of Sector 0, PI-codes 32-47 are evenly distributed across Zone 2 of Sector 1, etc. It should be understood that other implementations may have different numbers of phases, zones, sectors, and PI-codes.

### Example PI with Bias Generator

FIG. 4 is a block diagram of an example implementation of PI 220 with a bias generator, according to some embodiments of the disclosure. PI 220 includes phase selector 410, a set of PI unit cells 420, phase interpolation digital-to-analog converter (PI-DAC) 430, bias generator 440, and load 450. The interpolated clock 274 is output at a point between the PI unit cells 420 and the load 450. As described in detail below, the bias generator 440 is coupled to one or more phase interpolation cells, e.g., one or more of the PI unit cells 420, and the bias generator 440 is configured to apply a dynamic bias to the phase interpolation cell(s), where the dynamic bias is based on a phase zone (e.g., one of the zones in FIG. 3) that corresponds to a portion of a phase range (e.g., the phase range illustrated in FIG. 3) generated by PI 220.

PI 220, and specifically phase selector 410, receives a plurality of phase signals φ0, φ1, . . . , φ7, which correspond to the phases φ0 through φ7 illustrated in FIG. 3. The phase signals may be generated by a DLL, such as DLL 230 described above with respect to FIG. 2. Phase selector 410 receives the phase signals and selects an adjacent pair of the phase signals, denoted as φₖ and φₖ₊₁. As described with respect to FIG. 3, the selected adjacent pair corresponds to a phase sector within the phase range of the PI 220, and a phase zone (e.g., a phase zone used to select a dynamic bias) corresponds to a portion of a phase sector. The adjacent pair of phase signals φₖ and φₖ₊₁ are provided to the PI unit cells 420.

The PI unit cells 420 collectively implement the phase interpolation function of the PI 220. PI unit cells 420 may also be referred to as unit cells, interpolation elements, or PI elements. In some embodiments, the phase interpolator 220 is implemented using current-mode logic (CML), where each PI unit cell 420 includes one or more transconductance-based circuit elements (e.g., a gm-cell) configured to generate a current contribution corresponding to a phase signal (e.g., φₖ or φₖ₊₁). In one example implementation, a PI unit cell 420 includes a first transconductance element or first gm-cell configured to generate a current contribution from phase signal φₖ and a second transconductance element or second gm-cell configured to generate a current contribution from phase signal φₖ₊₁. The magnitude of the current contribution(s) produced by each PI unit cell 420 may be controlled based on an applied interpolation weight, e.g., the weights from the PI-DAC 430. In some embodiments, the PI unit cells 420 are arranged as an array and may be organized into groups, where PI unit cells 420 within a given group share a common baseline bias or nominal operating point. Organizing the PI unit cells 420 into groups in this manner can facilitate control of the effective transconductance and delay contribution of different portions of the unit cell array.

PI-DAC 430 is configured to receive PI-code 262 from PI-code accumulator 260 and to generate corresponding interpolation weights, referred to as α and 1−α, based on the PI-code 262. The interpolation weights control the relative contribution of the selected phase signals φₖ and φₖ₊₁ within the PI unit cells 420. The interpolated clock 274 signal is formed by combining contributions from multiple PI unit cells 420. In this example, the outputs of the PI unit cells 420 are coupled to a load 450, which provides an electrical summation point for the PI unit cells 420 and converts the combined contributions into the interpolated clock signal 274.

Each PI unit cell 420 is configured to contribute a corresponding current component to an output node based on the phase signals φₖ and φₖ₊₁ and the interpolation weights α and 1−α that control how the selected phase signals φₖ and φₖ₊₁ are weighted within the PI unit cells 420. In some embodiments, the PI unit cells 420 are organized as a plurality of groups (e.g., groups of gm-cells) that share a common bias. For example, a first group of PI unit cells 420 may receive a first bias current and a second group of PI unit cells 420 may receive a second bias current, where the bias currents are provided by one or more baseline bias sources used to establish nominal operating points for the PI unit cells. Grouping the PI unit cells 420 in this manner can provide a convenient way to control the effective transconductance and delay contribution of different portions of the unit-cell array. One or more of these bias levels may be further adjusted or selected using bias generator 440.

The bias generator 440 is coupled to the PI unit cells 420 and is configured to apply a dynamic or programmable bias to at least one of the PI unit cells 420, e.g., to one or more groups of PI unit cells 420. The bias generator 440 is configured to select or adjust the dynamic bias based on a phase zone corresponding to a portion of the phase sector in which the PI 220 is currently operating. As described with respect to FIG. 3, the phase zone may be determined based on the PI-code 262. The applied bias may adjust a delay through the PI unit cell(s) 420 by modifying an operating characteristic of the PI unit cells 420, such as a bias current or bias voltage.

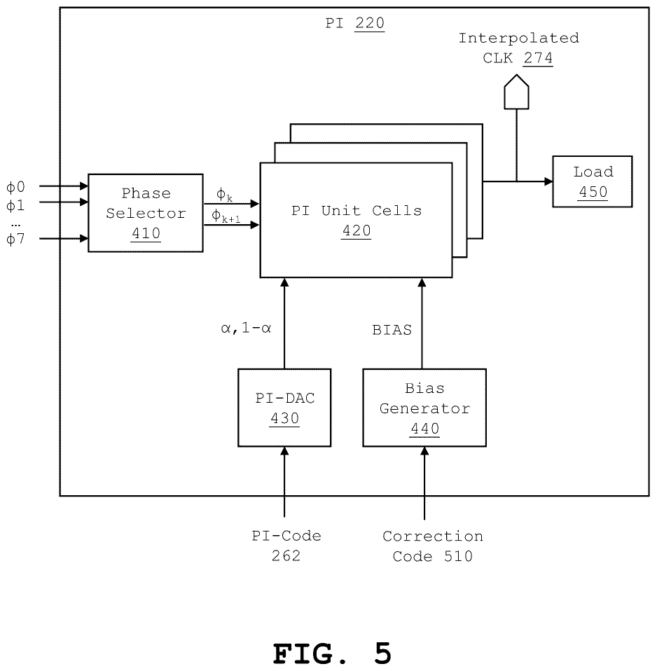

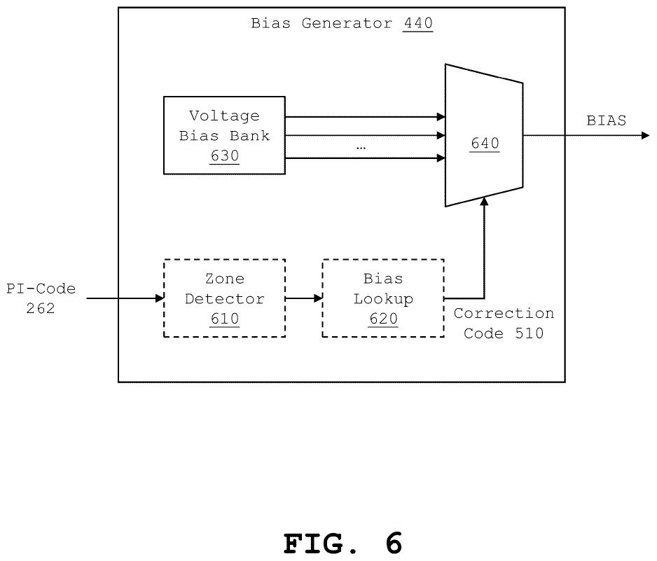

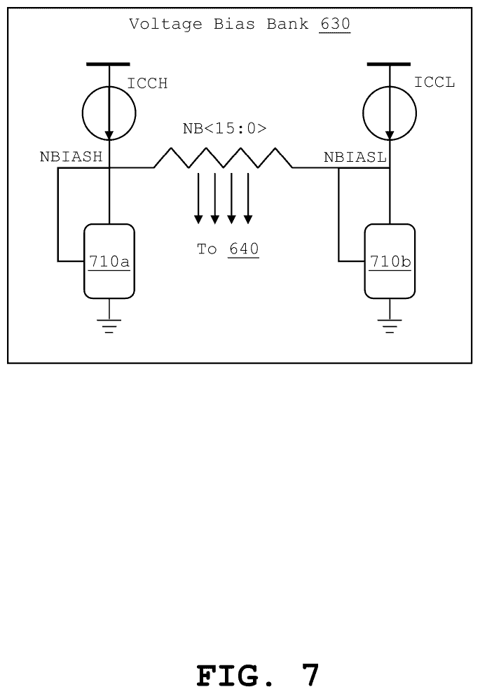

In some embodiments, the bias generator 440 determines the phase zone directly from the PI-code 262. This implementation is shown in FIG. 4, in which the bias generator 440 receives PI-codes 262 from the PI-code accumulator 260; the bias generator 440 may determine a phase zone corresponding to the PI-code 262, and then determine a bias value based on the phase zone. In other embodiments, the bias generator 440 receives a correction code, which may be derived from the PI-code 262 or from a mapping between PI-codes and phase zones. An example is shown in FIG. 5. The bias generator 440 may include circuitry for selecting a bias value from a plurality of available bias values, for example from a voltage bias bank, and coupling the selected bias value to the PI unit cells 420 based on the determined phase zone. Example details of the bias generator 440 are illustrated in FIGS. 6 and 7, described below.

By applying a zone-dependent dynamic bias to the PI unit cells 420, the PI 220 can mitigate nonlinearity in its phase response across the phase range. In particular, the bias applied by the bias generator 440 may reduce differential nonlinearity within a given phase zone, thereby reducing accumulated integrated nonlinearity across multiple PI-codes. Although FIG. 4 illustrates a single bias, PI 220 may include multiple groups of phase interpolation cells, and the bias generator 440 may apply the same or different biases to different subsets of the phase interpolation cells, as described in further detail below.

In some embodiments, the phase interpolator is implemented as a differential circuit. For example, PI unit cells 420 may generate complementary differential output signals, such as a positive output (OUTP) and a negative output (OUTN). In such embodiments, bias generator 440 may apply biasing to the phase interpolation cell 420 in a manner that affects both the positive and negative signal paths, such that the relative current contributions to OUTP and OUTN are adjusted while maintaining differential operation. Although FIG. 4 illustrates the PI 220 at a block level for clarity, it should be understood that the PI 220 may be implemented using a differential CML architecture having differential outputs.

### Example PI with Bias Generator that Receives Correction Code

FIG. 5 is a block diagram of a second example PI with a bias generator configured to receive a correction code, according to some embodiments of the disclosure. In the example of FIG. 4, bias generator 440 received PI-code 262 and generated the bias based on the PI-code, e.g., by determining a phase zone including the PI-code 262 and determining the bias based on the phase zone. In another embodiment, circuitry outside the PI 220 determines a correction code 510 (e.g., based on PI-code 262) and provides the correction code 510 to the PI 220, where the correction code 510 is input into the bias generator 440. The correction code 510 may correspond to a particular bias value, e.g., if the bias generator 440 can generate 16 bias signals, the correction code 510 may indicate one of the bias signals for the bias generator 440 to select and output to one or more of the PI unit cells 420.

### Example Bias Generator

FIG. 6 is a block diagram of the bias generator, according to some embodiments of the disclosure. Bias generator 440 includes a voltage bias bank 630 and selection circuitry 640. In some implementations, bias generator 440 further includes a zone detector 610 and bias lookup 620; in other implementations (e.g., the implementation of FIG. 5), the zone detector 610 and bias lookup 620 are omitted, so these are illustrated with dashed lines.

The zone detector 610 receives PI-code 262 and identifies a zone corresponding to the PI-code 262. For example, if the phase range generated by PI 220 includes 256 interpolated phases ranging from 0-255 and represented by the circle in FIG. 3, and the PI-code 262 is between 0 and 15, zone detector 610 outputs a signal corresponding to Zone 0. As another example, if the PI-code 262 is between 16 and 31, zone detector 610 outputs a signal corresponding to Zone 1. A zone detection signal may be a 4-bit signal, with 0000 representing Zone 0, 0001 representing Zone 1, 0010 representing Zone 2, and so forth.

The bias lookup 620 receives the zone detection signal and determines a correction code 510 corresponding to the zone. The correction code 510 represents one of the bias values from the voltage bias bank 630 to be output to one or more PI unit cells 420. For example, bias lookup 620 may include mapping circuitry associating each phase zone with a corresponding bias to be applied to the PI unit cells 420. A mapping between phase zones and corresponding biases may be learned during an initialization sequence or training operation that characterizes nonlinearity of the PI 220. Based on the measured nonlinearity, correction codes corresponding to respective phase zones may be determined and stored, e.g., in a lookup table (LUT). In some embodiments, the PI 220 may include multiple groups of PI unit cells 420 that can be separately controlled; in such embodiments, the bias lookup 620 may output two or more correction codes, with each correction code corresponding to a respective group of PI unit cells 420.

The voltage bias bank 630 is configured to generate a plurality of bias voltages. Selection circuitry 640 is coupled to the voltage bias bank 630 and receives the bias voltages generated by the voltage bias bank 630. Selection circuitry 640 may be implemented as a multiplexer, as shown in FIG. 6. Selection circuitry 640 is configured to couple a selected bias voltage from the voltage bias bank to one or more PI unit cells 420 based on the phase zone, e.g., based on correction code 510 for a particular phase zone, where the correction code 510 is provided by bias lookup 620 (as described above) or received at the PI 220 (as shown in FIG. 5).

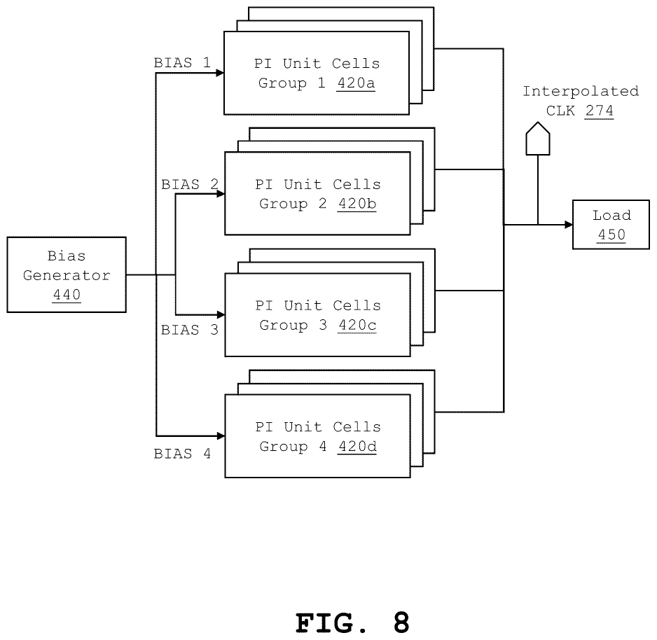

FIG. 7 illustrates an example implementation of the voltage bias bank 630, according to some embodiments of the disclosure. In this example, voltage bias bank 630 includes a resistive network coupled between two bias current sources, labelled as a first or high current source ICCH and a second or low current source ICCL. The resistive network has multiple tap points, where each tap point is configured to provide a corresponding bias voltage to selection circuitry 640, as illustrated in FIG. 7. In some implementations, the resistive network and associated tap points form a resistor-based digital-to-analog conversion (DAC) network that enables generation of selectable bias voltages corresponding to different bias current levels. The selection circuitry 640, shown in FIG. 6, can select one of the tap points, as discussed above. The selected bias voltage can be applied to a shared bias terminal or bias node of a set of PI unit cells 420 (e.g., one of the groups shown in FIG. 8) to control a bias current flowing through the transconductive elements (e.g., multiple pairs of gm-cells), thereby adjusting a transconductance and a delay contribution of the PI unit cells 420.

### Grouped PI Unit Cells

As noted above, in some embodiments, PI 220 includes multiple PI unit cells 420 which can be arranged in several groups, and each group can receive an independent bias value. FIG. 8 illustrates an example grouping of PI unit cells receiving different bias values, according to some embodiments of the disclosure. In the illustrated embodiment, the PI unit cells 420 are arranged in four groups, PI unit cells Group 1 420a, PI unit cells Group 2 420b, PI unit cells Group 3 420c, and PI unit cells Group 4 420d. Each group receives a bias (BIAS 1, BIAS 2, BIAS 3, or BIAS 4, respectively) from bias generator 440. Each group includes multiple unit cells that receive the same bias, e.g., each of the unit cells in Group 1 420a receives BIAS 1. Biases applied to different groups may be different, e.g., BIAS 1 applied to Group 1 420a may be different from BIAS 2 applied to Group 2 420b. Both BIAS 1 and BIAS 2 may be dynamic biases that are separately programmable. For example, selection circuitry 640 may receive two different correction codes 510, one corresponding to BIAS 1 for Group 1 420a and the other corresponding to BIAS 2 for Group 2 420b, from bias lookup 620 or from a source outside of PI 220 (as in FIG. 5). In some implementations, one or more groups receive a fixed bias that is constant across phase zones. For example, BIAS 3 and BIAS 4 may be fixed, such that Group 3 420c and Group 4 420d do not have dynamic biases that change during operation as the PI-code 262 moves into different phase zones. BIAS 3 and BIAS 4 may be determined during an initialization or calibration phase.

As the PI-code 262 varies to interpolate between adjacent input phases (e.g., φₖ and φₖ₊₁), each group of PI unit cells 420 contributes continuously to the interpolated clock 274. Interpolation may be achieved by adjusting relative phase weights applied to the PI unit cells 420 across the groups, such that the contribution associated with one input phase (e.g., φₖ) decreases while the contribution associated with the adjacent input phase (e.g., φₖ₊₁) correspondingly increases. In some embodiments, the bias values applied to one or more groups remain unchanged as the phase weights vary within a given phase zone, e.g., across Zone 1, dynamic BIAS 1 and BIAS 2 remain the same. When the PI-code 262 transitions across a boundary between phase zones (e.g., from Zone 1 to Zone 2), one or more group biases (e.g., BIAS 1 and BIAS 2) may be updated, after which interpolation continues using the updated bias values, while the phase weights continue to vary with the PI-code 262. In this manner, phase interpolation and zone-based bias adjustment are decoupled, enabling correction of nonlinearity without disrupting monotonic interpolation behavior.

While FIG. 8 illustrates four groups of PI unit cells 420, it should be understood that PI 220 may include any number of groups, e.g., one, two, three, four, or more groups of PI unit cells 420 receiving a corresponding number of dynamic biases, and one, two, three, four, or more groups of PI unit cells 420 receiving a corresponding number of fixed biases. Each group may have the same number of PI unit cells 420 (e.g., each group may have two, four, eight, or any other number of PI unit cells 420). Alternatively, groups may have different numbers of PI unit cells 420. As one example, PI 220 may have two groups of dynamically-biased unit cells receiving different biases, and one group of unit cells receiving a fixed bias, where the fixed-bias group includes more unit cells than either of the dynamically-biased groups.

### Example Method for PI-Code Monitoring

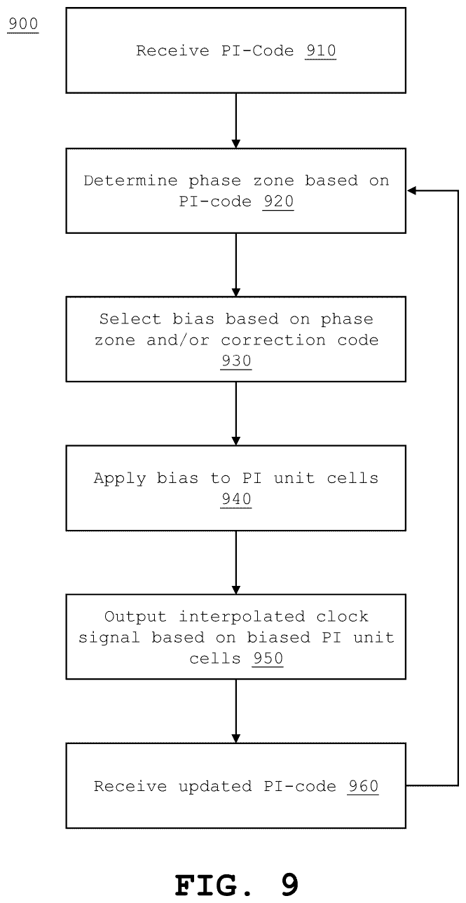

FIG. 9 is a flow chart illustrating a method 900 for nonlinearity correction for a PI, according to some embodiments of the present disclosure. Method 900 may be performed by components illustrated in FIGS. 4-8. For example, method 900 may be performed by the PI 220 described above. Although the method is described in connection with particular hardware components for clarity, it should be understood that the method may be performed by other suitable circuitry or combinations of circuitry.

In 910, PI 220 receives a code corresponding to a desired interpolated phase. For example, PI 220 receives a PI-code 262 generated by PI-code accumulator 260, as described above with respect to FIGS. 2 and 4. The received PI-code 262 identifies a location within a phase range of PI 220.

In 920, PI 220 determines a phase zone corresponding to the received PI-code. The phase zone corresponds to a portion of the phase range of PI 220 and may represent a subdivision of a phase sector associated with an adjacent pair of phase signals bounding the phase sector, as described above with respect to FIG. 3. In some embodiments, bias generator 440 determines the phase zone based on the PI-code 262, as described with respect to FIGS. 4 and 6. In other embodiments, PI 220 does not determine the phase zone, but instead receives a correction code 510 from circuitry outside the PI 220, e.g., as described with respect to FIG. 5.

In 930, bias generator 440 selects a bias for one or more interpolation elements (e.g., one or more PI unit cells 420) of the PI 220 based on the phase zone (e.g., if the bias generator 440 determines the phase zone in 920) and/or the correction code (e.g., if the PI 220 receives the correction code 510, as shown in FIG. 5). The selected bias corresponds to one of a plurality of bias values generated by bias generator 440, for example by voltage bias bank 630. A particular bias value may be selected based on the correction code 510 using selection circuitry 640, as described above with respect to FIGS. 6 and 7. In some embodiments, multiple biases are selected, e.g., a first bias (e.g., BIAS 1) for a first group of unit cells, and a second bias (e.g., BIAS 2) for a second group of unit cells, as described with respect to FIG. 8.

In 940, PI 220 applies the selected bias to one or more interpolation elements (e.g., one or more PI unit cells 420), which may adjust a delay through the PI unit cells. In particular, the applied bias may modify a bias current or bias voltage associated with a transconductance-based circuit element within the PI unit cells 420, as described above. In some embodiments, PI 220 applies a first selected bias to a first group of PI unit cells (e.g., 420a) and applies a second selected bias to a second group of PI unit cells (e.g., 420b), as described with respect to FIG. 8.

In 950, PI 220 generates an interpolated clock signal based on outputs from the biased interpolation elements. PI 220 may generate the interpolated clock signal by interpolating between two adjacent phase signals using the PI unit cells 420, which are operating with the applied bias, as described above with respect to FIG. 4. If PI 220 includes multiple groups of PI unit cells 420, the interpolated clock signal is generated based on outputs from each of the groups of PI unit cells (e.g., groups 420a, 420b, 420c, and 420d), as described with respect to FIG. 8.

In 960, PI 220 receives an updated PI-code 262 corresponding to an updated desired interpolated phase. The method proceeds to 920, in which PI 220 determines an updated phase zone corresponding to the updated PI-code 262. If the phase zone has changed, the bias generator 440 selects a second bias corresponding to the updated phase zone. PI 220 applies the second bias to the PI unit cells and generates an updated interpolated clock signal based on outputs from the PI unit cells with the applied second bias.

### SELECT EXAMPLES

Example 1 provides a phase interpolator with nonlinearity mitigation, the phase interpolator including a phase interpolation cell; and a bias generator coupled to the phase interpolation cell, the bias generator configured to apply a dynamic bias to the phase interpolation cell, the dynamic bias based on a phase. For example, the dynamic bias may be based on a phase zone corresponding to a portion of a phase range generated by the phase interpolator.

Example 2 provides the phase interpolator of example 1, where the bias generator includes a voltage bias bank configured to generate a plurality of bias voltages; and selection circuitry configured to couple a selected bias voltage from the voltage bias bank to the phase interpolation cell based on the phase.

Example 3 provides the phase interpolator of example 2, where the voltage bias bank includes a resistive network having a plurality of tap points, each tap point configured to provide a corresponding bias voltage.

Example 4 provides the phase interpolator of example 2 or example 3, where the bias generator is further configured to determine a phase zone based on an interpolation code of the phase interpolator.

Example 5 provides the phase interpolator of any of examples 1-4, where the phase is a phase zone corresponding to a portion of a phase range generated by the phase interpolator.

Example 6 provides the phase interpolator of example 5, where the phase interpolator includes mapping circuitry associating a plurality of phase zones of the phase interpolator with respective biases applied to the phase interpolation cell.

Example 7 provides the phase interpolator of example 5 or 6, where the phase interpolator further includes a phase selector configured to receive a plurality of phase signals and to select an adjacent pair of the phase signals, where the phase zone corresponds to a portion of a phase sector between the adjacent pair of phase signals.

Example 8 provides the phase interpolator of any of examples 1-7, where the phase interpolation cell is one of a plurality of phase interpolation cells in the phase interpolator, and the bias generator applies the dynamic bias to at least two of the plurality of phase interpolation cells.

Example 9 provides the phase interpolator of example 8, where the phase interpolator comprises a plurality of groups of phase interpolation cells, and the dynamic bias is a first bias applied to a first group of the plurality of groups of phase interpolation cells, the first group comprising the at least two of the plurality of phase interpolation cells.

Example 10 provides the phase interpolator of example 9, where each group of the plurality of groups of phase interpolation cells receives a respective bias.

Example 11 provides the phase interpolator of example 9, where a first subset of the groups each receive a respective fixed bias, and a second subset of the groups each receive a respective dynamic bias.

Example 12 provides the phase interpolator of any of examples 1-11, where the dynamic bias applied to the phase interpolation cell is configured to mitigate nonlinearity in a phase response of the phase interpolator across a phase range of the phase interpolator.

Example 13 provides the phase interpolator of any of examples 1-12, where the dynamic bias applied to the phase interpolation cell is configured to adjust a delay through the phase interpolation cell.

Example 14 provides a method for mitigating nonlinearity in a phase interpolator (PI), the method including selecting a bias for a unit cell of the PI based on a phase zone of the PI; applying the bias to the unit cell to adjust a delay through the unit cell; and generating an interpolated clock signal based on an output from the unit cell with the applied bias.

Example 15 provides the method of example 14, further including receiving a correction code corresponding to the phase zone; and selecting the bias for the unit cell based on the correction code.

Example 16 provides the method of example 14, further including receiving a code corresponding to a desired interpolated phase for the PI; and determining a phase zone corresponding to a portion of a phase range of the phase interpolator.

Example 17 provides the method of any of examples 14-16, further including selecting a second bias for the unit cell of the PI based on an updated phase zone; applying the second bias to the unit cell to adjust the delay through the unit cell; and generating an updated interpolated clock signal based on the output from the unit cell with the applied second bias.

Example 18 provides the method of any of examples 14-17, where the unit cell is one of a first group of unit cells, the method further including selecting a second bias for a second group of unit cells; and applying the second bias to the second group of unit cells; where the interpolated clock signal is generated based on outputs from the first group of unit cells and the second group of unit cells.

Example 19 provides a device for generating an interpolated phase, the device including means for selecting a bias for an interpolation element of a phase interpolator (PI) based on a phase; means for applying the selected bias to the interpolation element to adjust a delay through the interpolation element; and means for generating an interpolated clock signal based on an output from the interpolation element with the applied bias

Example 20 provides the device of example 19, where the means for applying the selected bias includes means for applying the selected bias to a group of interpolation elements that collectively contribute to the interpolated clock signal.

Example 21 provides the device of example 20, where the group of interpolation elements includes a plurality of transconductance-based elements coupled to a shared bias node.

Example 22 provides the device of example 20 or 21, where the group of interpolation elements receives a dynamically selected bias, and a second group of interpolation elements receives a fixed bias.

Example 23 provides the device of any of examples 19-22, where the means for applying the selected bias includes means for generating the bias using a resistor-based digital-to-analog (DAC) conversion network having multiple tap points.

Example 24 provides the device of example 23, where the means for selecting the bias includes means for selecting one of the tap points based on a portion of a phase range corresponding to the interpolated phase.

Example 25 provides an apparatus comprising means for performing any one of the methods of examples 13-18.

Example 26 provides a transmitter having a transmit portion and a digital signal processor according to any one of examples 1-12 and 20-24.

Example 27 provides a receiver having a receive portion and a digital signal processor according to any one of examples 1-12 and 20-24.

Example 28 provides a transceiver having a transmit portion, a receive portion, and a digital signal processor according to any one of examples 1-12 and 20-24.

### Variations and Other Notes

The detailed description, such as the “Select examples” section, provides various examples of the embodiments disclosed herein.

As used herein, the term “coupled to” or “coupled with” refers to a relationship between electronic components or circuit elements wherein the components are in electronic communication with one another and capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/−20% of a target value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods and devices of this disclosure each have several innovative aspects, no single one of which is solely responsible for all desirable attributes disclosed herein. Details of one or more implementations of the subject matter described in this specification are set forth in the description and the accompanying drawings.

1. A phase interpolator with nonlinearity mitigation, the phase interpolator comprising:
a phase interpolation cell; and
a bias generator coupled to the phase interpolation cell, the bias generator configured to apply a dynamic bias to the phase interpolation cell, the dynamic bias based on a phase.

2. The phase interpolator of claim 1, wherein the bias generator comprises:
a voltage bias bank configured to generate a plurality of bias voltages; and
selection circuitry configured to couple a selected bias voltage from the voltage bias bank to the phase interpolation cell based on the phase.

3. The phase interpolator of claim 2, wherein the voltage bias bank comprises a resistive network having a plurality of tap points, each tap point configured to provide a corresponding bias voltage.

4. The phase interpolator of claim 2, wherein the bias generator is further configured to determine a phase zone based on an interpolation code of the phase interpolator.

5. The phase interpolator of claim 1, wherein the phase is a phase zone corresponding to a portion of a phase range generated by the phase interpolator.

6. The phase interpolator of claim 5, wherein the phase interpolator comprises mapping circuitry associating a plurality of phase zones of the phase interpolator with respective biases applied to the phase interpolation cell.

7. The phase interpolator of claim 5, wherein the phase interpolator further comprises a phase selector configured to receive a plurality of phase signals and to select an adjacent pair of the phase signals, wherein the phase zone corresponds to a portion of a phase sector between the adjacent pair of phase signals.

8. The phase interpolator of claim 1, wherein the phase interpolation cell is one of a plurality of phase interpolation cells of the phase interpolator, and the bias generator applies the dynamic bias to at least two of the plurality of phase interpolation cells.

9. The phase interpolator of claim 8, wherein the phase interpolator comprises a plurality of groups of phase interpolation cells, and the dynamic bias is a first bias applied to a first group of the plurality of groups of phase interpolation cells, the first group comprising the at least two of the plurality of phase interpolation cells.

10. The phase interpolator of claim 9, wherein each group of the plurality of groups of phase interpolation cells receives a respective bias.

11. The phase interpolator of claim 10, wherein a first subset of the groups each receive a respective fixed bias, and a second subset of the groups each receive a respective dynamic bias.

12. The phase interpolator of claim 1, wherein the dynamic bias applied to the phase interpolation cell is configured to mitigate nonlinearity in a phase response of the phase interpolator across a phase range of the phase interpolator.

13. The phase interpolator of claim 1, wherein the dynamic bias applied to the phase interpolation cell is configured to adjust a delay through the phase interpolation cell.

14. A method for mitigating nonlinearity in a phase interpolator (PI), the method comprising:
selecting a bias for a unit cell of the PI based on a phase zone of the PI;
applying the bias to the unit cell to adjust a delay through the unit cell; and
generating an interpolated clock signal based on an output from the unit cell with the applied bias.

15. The method of claim 14, further comprising:
receiving a correction code corresponding to the phase zone; and
selecting the bias for the unit cell based on the correction code.

16. The method of claim 14, further comprising:
receiving a code corresponding to a desired interpolated phase for the PI; and
determining a phase zone corresponding to a portion of a phase range of the phase interpolator.

17. The method of claim 14, further comprising:
selecting a second bias for the unit cell of the PI based on an updated phase zone;
applying the second bias to the unit cell to adjust the delay through the unit cell; and
generating an updated interpolated clock signal based on the output from the unit cell with the applied second bias.

18. The method of claim 14, wherein the unit cell is one of a first group of unit cells, the method further comprising:
selecting a second bias for a second group of unit cells; and
applying the second bias to the second group of unit cells;
wherein the interpolated clock signal is generated based on outputs from the first group of unit cells and the second group of unit cells.

19. A device for generating an interpolated phase, the device comprising:
means for selecting a bias for an interpolation element of a phase interpolator (PI) based on a phase;
means for applying the selected bias to the interpolation element to adjust a delay through the interpolation element; and
means for generating an interpolated clock signal based on an output from the interpolation element with the applied bias.

20. The device of claim 19, wherein the means for applying the selected bias comprises means for applying the selected bias to a group of interpolation elements that collectively contribute to the interpolated clock signal.

21. The device of claim 20, wherein the group of interpolation elements comprises a plurality of transconductance-based elements coupled to a shared bias node.

22. The device of claim 20, wherein the group of interpolation elements receives a dynamically selected bias, and a second group of interpolation elements receives a fixed bias.

23. The device of claim 19, wherein the means for applying the selected bias comprises means for generating the bias using a resistor-based digital-to-analog (DAC) conversion network having multiple tap points.

24. The device of claim 23, wherein the means for selecting the bias comprises means for selecting one of the tap points based on a portion of a phase range corresponding to the interpolated phase.
